(19) United States
(12) Patent Application Publication
(10) Pub. No.: US 2005/0242975 A1
(43) Pub. Date: Nov. 3, 2005

(54) Self-powered digital audio devices

(76) Inventor: Larry Kirn, East Lansing, MI (US)

Correspondence Address: John G. Posa;Gifford, Krass, Groh, Sprinkle,, Anderson & Citkowski, P.C., PO Box 7021, Troy, MI, 48007-7021, US

(21) Appl. No.: 11/106,290

(22) Filed: Apr. 14, 2005

Related U.S. Application Data
(60) Provisional application No. 60/562,760, filed on Apr. 14, 2004.

(51) Int. Cl. H03M 7/00

(52) U.S. Cl. 341/50

(57) ABSTRACT

An integrated speaker or microphone derives its power from an incoming signal, thereby minimizing or eliminating the need for an external amplifier or power supply. A system according to the invention includes an audio transducer, an input for receiving a digital audio signal, an amplifier for amplifying the digital audio signal to or from the audio transducer, and a rectifier for rectifying the digital audio signal for use in powering the amplifier. A filter may be included for filtering the output of the rectifier. In the preferred embodiment, the digital audio signal uses a non-return-to-zero (NRZ) encoding scheme. When the transducer is a microphone, it is connected to an analog-to-digital (A/D) converter, also powered by the rectified digital audio signal.

### REFERENCE TO RELATED APPLICATION

This application claims priority to U.S. Provisional Patent Application Ser. No. 60/562,760, filed Apr. 14, 2004, the entire content of which is incorporated herein by reference.

### FIELD OF THE INVENTION

The present invention is method whereby digital audio devices derive their power directly from the incoming signal, utilizing both hardware and software protocol techniques.

### BACKGROUND OF THE INVENTION

Audio speakers, including headphones, are typically driven by stand-alone amplifiers which often utilize external power supplies. Especially in the case of headphones, this approach can be cumbersome, particularly as digital sources facilitate integration. Furthermore, digital audio sources, such as digital microphones, often retain power supply complexity of earlier analog counterparts.

There exists a need of a simple self-contained method whereby audio input/output devices may be powered by their input or output data streams.

### SUMMARY OF THE INVENTION

The present invention provides an integrated speaker or microphone which derives its power from an incoming signal, thereby minimizing or eliminating the need for an external amplifier or power supply.

In terms of apparatus, a self-powered digital audio system according to the invention includes an audio transducer, an input for receiving a digital audio signal, an amplifier for amplifying the digital audio signal to or from the audio transducer, and a rectifier for rectifying the digital audio signal for use in powering the amplifier. A filter may be included for filtering the output of the rectifier. In the preferred embodiment, the digital audio signal uses a non-return-to-zero (NRZ) encoding scheme. When the transducer is a microphone, it is connected to an analog-to-digital (A/D) converter, also powered by the rectified digital audio signal.

### BRIEF DESCRIPTION OF THE DRAWINGS

FIG. 1 is a block diagram of an embodiment of the present invention used in conjunction with a microphone; and

FIG. 2 is a block diagram of an embodiment of the present invention used in conjunction with a speaker.

### DETAILED DESCRIPTION OF THE INVENTION

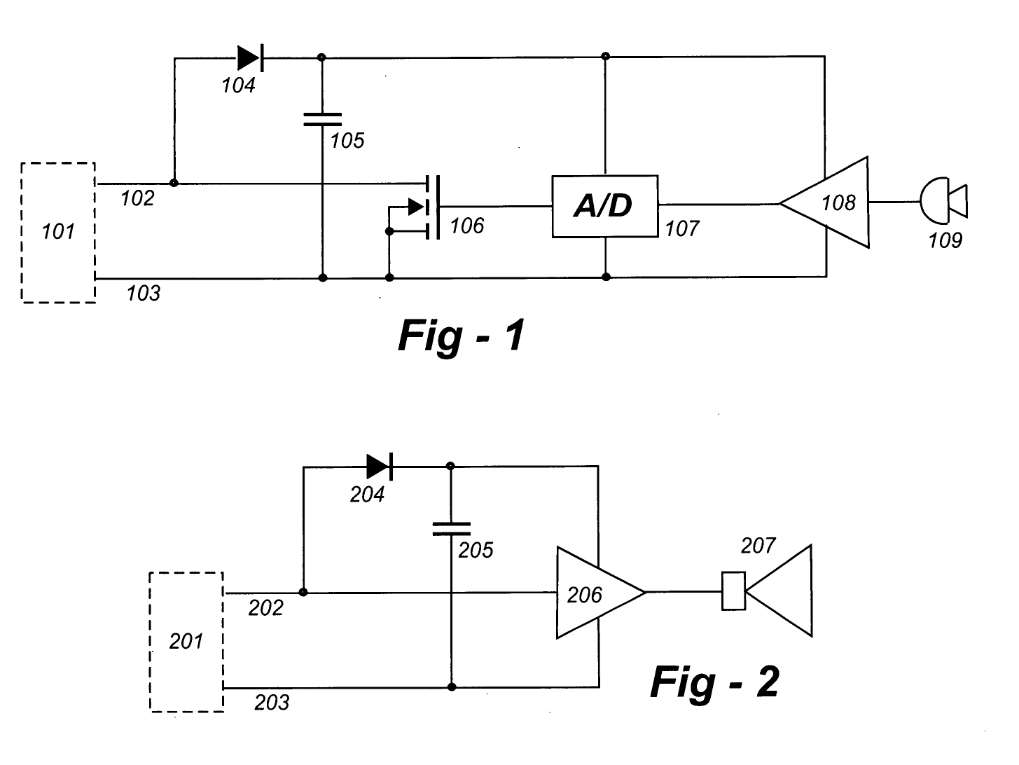

FIG. 1 is a block diagram of an embodiment of the present invention used in conjunction with a microphone. Connector 101 includes wire 102, which carries a digital audio signal, and wire 103, which serves as the signal and power return paths for analog-to-digital converter 107 and amplifier 108. The digital audio signal carried by wire 102 is rectified by diode 104. The output of diode 104 is filtered by capacitor 105, and applied as power source to analog-to-digital converter 107 and amplifier 108. The output of microphone 109 drives the input of amplifier 108, which drives the input of analog-to-digital converter 107.

The output of analog-to-digital converter 107 drives the control input of switching device 106, which selectively shunts wire 103 to 102. It is assumed that the receiving device connected to connector 101 provides limited DC current to wire 102, allowing wire 102 to switch between two voltage states under control of switching device 106. In order to limit low-frequency fluctuations on the supply voltage supplied by diode 104, a non-return-to-zero (NRZ) encoding scheme is used by analog-to-digital converter 107.

FIG. 2 is a block diagram of an embodiment of the present invention used in conjunction with a speaker. Connector 201 includes wire 202, which carries a digital audio signal; and wire 203, which serves as the signal and power return paths for amplifier 206. The digital audio signal carried by wire 202 is rectified by diode 204. The output of diode 204 is filtered by capacitor 205, and applied as power source to digital amplifier 206. The output of digital amplifier 206 directly drives speaker 207. In order to limit low-frequency fluctuations on the supply voltage supplied by diode 104, a non-return-to-zero (NRZ) encoding scheme is supplied to digital amplifier 206.

Assuming the existence of positive-going data pulses on wires 101 and 202, it can be seen by the above explanations that the data stream carried by wires 101 and 202 is used to directly provide power to the appropriate audio input/output devices. Although single-channel embodiments are disclosed, those of skill in the art of digital audio will readily appreciate that multiple-channel instances of the invention will function by extrapolation.

I claim:

1. A self-powered digital audio system, comprising:
an audio transducer;
an input for receiving a digital audio signal;
an amplifier for amplifying the digital audio signal to or from the audio transducer; and
a rectifier for rectifying the digital audio signal for use in powering the amplifier.

2. The self-powered digital audio system of claim 1, wherein the digital audio signal uses a non-return-to-zero (NRZ) encoding scheme.

3. The self-powered digital audio system of claim 1, further including a filter for filtering the output of the rectifier.

4. The self-powered digital audio device of claim 1, wherein:
the transducer is a microphone; and
the microphone is connected to an analog-to-digital (A/D) converter also powered by the rectified digital audio signal.

5. The self-powered digital audio device of claim 1, wherein the transducer is a speaker.
